(19) United States
(12) Patent Application Publication
(10) Pub. No.: US 2021/0088552 A1
(43) Pub. Date: Mar. 25, 2021

(54) Conductive Member Using Copper-Silver Alloy, Contact Pin and Device

(71) Applicants: Kyosei Co., Ltd., Tokyo (JP); National Institute for Materials Science, Ibaraki (JP)

(72) Inventors: Tsutomu SATO, Tokyo (JP); Yoshikazu SAKAI, Ibaraki (JP); Akihiro KIKUCHI, Ibaraki (JP)

(73) Assignees: Kyosei Co., Ltd., Tokyo (JP); National Institute of Materials Science, Ibaraki (JP)

(21) Appl. No.: 16/629,963

(22) PCT Filed: Jul. 9, 2018
(86) PCT No.: PCT/JP2018/025884

§ 371 Date: Jan. 10, 2020

(30) Foreign Application Priority Data
Jul. 10, 2017 (JP) 2017-135081

(51) Int. Cl. G01R 1/067; C22C 9/00; C22C 1/02; C23F 1/18

(52) U.S. Cl. CPC G01R 1/06755; G01R 1/06722; C23F 1/18; C22C 1/02; C22C 9/00

(57) ABSTRACT

The present invention focuses on a material constituting a contact pin and a processing technique of the material, and is directed to manufacturing a conductive member by using a material and a processing technique which are different from those in the related art.

The conductive member is obtained by applying etching treatment to a copper-silver alloy including copper and silver while using at least copper alloy etching liquid, but silver etching liquid may also be selectively added to the copper alloy etching liquid.

### TECHNICAL FIELD

The present invention is related to a conductive member, a contact pin, and a device using a copper-silver alloy, and particularly related to a conductive member, a contact pin, and a device using the copper-silver alloy and used for inspection of a semiconductor wafer, a PKG, and the like.

### BACKGROUND ART

Patent Literature 1 discloses a contact for an electronic device, and the contact includes: a contact portion having a predetermined shape and contacting a lead of an object to be tested, namely, an integrated circuit; an upper contact pin including two support protrusions and a main body; a lower contact pin coupled to the upper contact pin so as to be orthogonal to the upper contact pin; and a spring fitted across a predetermined area between the upper contact pin and the lower contact pin. The upper contact pin and the lower contact pin are manufactured by machining a rod-shaped copper alloy material and applying gold plating.

### CITATION LIST

### Patent Literature

Patent Literature 1: Abstract and Paragraph [0006] of JP 2008-516398 A

### SUMMARY OF INVENTION

### Technical Problem

However, a contact (tester) disclosed in Patent Literature 1 has a surface applied with gold plating, but since the gold generally has conductivity inferior to conductivity of an alloy, in a case of using an upper contact pin and a lower contact pin which are gold-plated, it can be hardly said that the gold is an optimum material in terms of the conductivity and strength. In a most advanced semiconductor device, pitches are miniaturized more and more and a large amount of current tends to flow, and therefore, a semiconductor wafer can be hardly inspected with the gold-plated contact pin thereafter.

The present invention focuses on a material constituting a contact pin and a processing technique of the material, and is directed to manufacturing a contact pin by using a material and a processing technique different from those disclosed in Patent Literature 1.

Additionally, the present invention is directed to providing not only the contact pin but also a conductive member, a tester unit, and an inspection device using the material.

### Solution to Problem

To solve the above-described problems, the conductive member of the present invention is obtained by applying etching treatment to a copper-silver alloy including copper and silver while using at least copper alloy etching liquid.

Silver etching liquid may also be added to the copper alloy etching liquid.

Additionally, the contact pin of the present invention is manufactured by using the above-described conductive member.

Furthermore, various kinds of devices can be manufactured by using the above-described conductive member.

There devices herein may include, for example, a connector like an interposer, a probe, a tester including an IC socket, an industrial spring used for a voice coil motor or the like, a suspension wire of an optical image stabilizer for camera shake correction, and the like.

### BRIEF DESCRIPTION OF DRAWINGS

FIG. 1 is a schematic view of a contact pin 1000 of an embodiment of the present invention.

FIG. 2 is an explanatory view of a method of manufacturing the contact pin 1000 illustrated in FIG. 1.

FIG. 3 is a schematic configuration view of a manufacturing device of the contact pin 1000 of the embodiment of the present invention.

FIG. 4 is a diagram illustrating evaluation results of the contact pin 1000 manufactured by using a copper-silver alloy plate manufactured while setting, to 6 wt %, an additive amount of silver to copper.

FIG. 5 is a diagram illustrating evaluation results of the contact pin 1000 manufactured by using a copper-silver alloy plate manufactured while setting, to 10 wt %, an additive amount of silver to copper.

FIG. 6 is an explanatory diagram of a modified example of the manufacturing device in FIG. 3.

### REFERENCE SIGN LIST

10 Pipe
15 Mask pattern
20 Exposure device
30 Rotating device
50, 60 Liquid tank
100 Copper-silver alloy body
1000 Contact pin

### Description of Embodiments

Hereinafter, an embodiment of the present invention will be described with reference to the drawings.

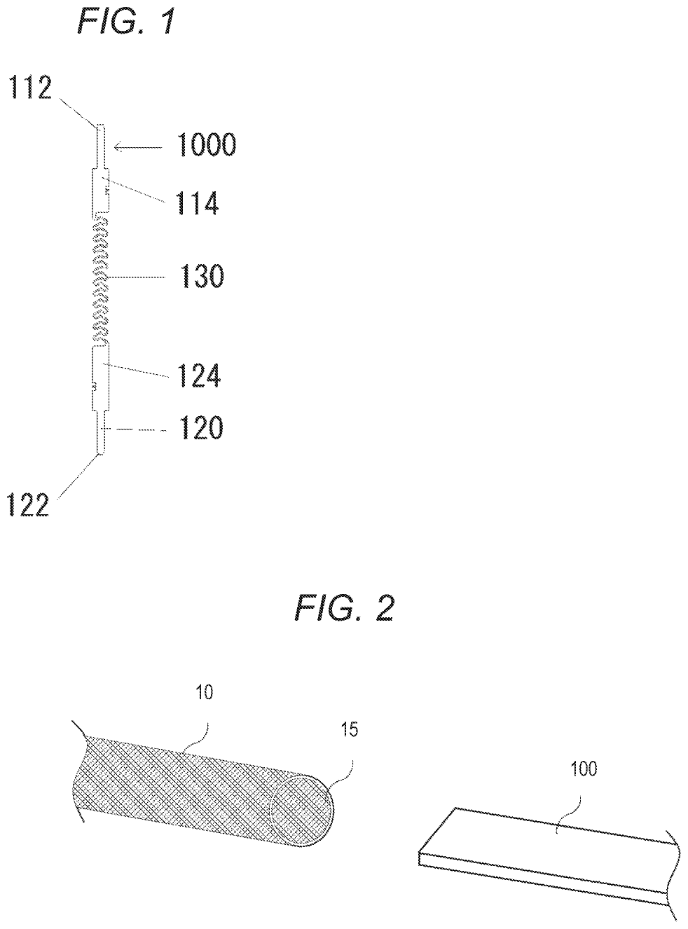

FIG. 1 is a schematic view of a contact pin 1000 of an embodiment of the present invention. The contact pin 1000 illustrated in FIG. 1 is used in an inspection device or the like that directly contacts a semiconductor wafer to inspect whether desired current flows in a semiconductor wafer.

The contact pin 1000 includes: a spring portion 130 formed in a substantially snake-like S shape; base portions 114 and 124 to provide strength to a main body of the contact pin 1000; and an upper contact 112 and a lower contact 122 provided adjacent to the base portions 114 and 124 respectively. A material of the contact pin 1000 is a copper-silver alloy, and here the contact pin 1000 has a planar shape, but may also have a three-dimensional shape like a cylindrical shape.

The respective portions of the contact pin 100 may have the following sizes although not limited thereto.

Spring portion 130: an entire width of about 1 mm, a wire diameter of about 0.2 mm, and an entire length of about 8 mm,

Base portion 114: a width of about 1 mm, and a length of about 3 mm,

Base portion 124: a width of about 1 mm, and a length of about 4 mm,

Upper contact 112 and lower contact 122: a width of about 0.5 mm, and a length of about 2 mm.

Here, it is known that a copper alloy generally has strength and conductivity which are in a trade-off relation in that: when the strength is high, the conductivity is low; and when the conductivity is high in contrast, the strength is low. Accordingly, in the present embodiment, a copper-silver alloy plate having high strength and high conductivity is manufactured by devising a manufacturing process of the copper-silver alloy plate.

Furthermore, an etching rate of etching is different between a silver portion and a copper portion constituting the copper-silver alloy. Here, most of the copper-silver alloy according to the present embodiment is formed from copper, and the strength and the conductivity thereof are affected by an additive amount of silver to the copper. For this reason, the copper-silver alloy plate is etched under the conditions whereby the strength and the conductivity required for the contact pin 1000 can be obtained. Hereinafter, a description will be provided for specific techniques: (1) a manufacturing process of a copper-silver alloy plate; and (2) an etching process of the copper-silver alloy plate.

(1) Manufacturing Process of Copper-Silver Alloy Plate

First, prepare copper and silver to constitute a copper-silver alloy plate, respectively. As the copper, prepare, for example, electrolytic copper or oxygen-free copper which is a commercially-available product and shaped into a strip shape in a size of 10 mm33 30 mm×50 mm. As the silver, prepare granular silver having a general shape with a primary diameter of about 2 mm to 3 mm. Meanwhile, as the oxygen-free copper, it may be possible to use a flat plate having a size like 10 mm to 30 mm×10 mm to 30 mm×2 mm to 5 mm, for example.

An additive amount of the silver to the copper is in a range of 0.2 wt % to 15 wt %, preferably in a range of 0.3 wt % to 10 wt %, more preferably in a range of 0.5 wt % to 6 wt %. The reason is that: considering reduction in a manufacturing cost of the copper-silver alloy plate, it is preferable that the additive amount of the silver be relatively little, however, when the additive amount is little like less than 0.5 wt % silver, the strength required for the contact pin 1000 cannot be achieved.

Next, charge the copper added with the silver under the above-described conditions into a melting furnace or the like, such as a high-frequency or low-frequency vacuum melting furnace including a Tamman furnace. Then, turn on the melting furnace to raise a temperature to about 1200° C., for example, and cast a copper-silver alloy by sufficiently melting the copper and the silver.

After that, apply solutionizing heat treatment to the copper-silver alloy that has been made into an ingot by the casting. At this time, in a case where the copper-silver alloy is cast in the air, a surface of the ingot is oxidized. Therefore, grind the oxidized portion. On the other hand, it is also possible to cast the copper-silver alloy in an inert atmosphere such as a nitrogen gas or an argon gas, and in this case, the surface grinding processing for the ingot becomes unnecessary. After the application of the solutionizing heat treatment to the copper-silver alloy, apply cold rolling and perform precipitation heat treatment at 350° C. to 550° C., for example.

Table 1 is a table representing measurement results of the strength and the conductivity of the copper-silver alloy plate in the embodiment of the present invention.

TABLE 1

| | | |
|---|---|---|
| THICKNESS | TENSILE | CONDUCTIVITY |
| [mm] | STRENGTH [MPa] | [% IACS] |

IN CASE OF ADDITIVE AMOUNT OF
SILVER TO COPPER IS 2 wt %

| | | |
|---|---|---|
| 0.4 | 800 | 86.0 |
| 0.3 | 825 | 85.0 |
| 0.2 | 850 | 84.5 |
| 0.1 | 890 | 83.0 |

IN CASE OF ADDITIVE AMOUNT OF
SILVER TO COPPER IS 3 wt %

| | | |
|---|---|---|
| 0.4 | 900 | 82.5 |
| 0.3 | 940 | 82.0 |
| 0.2 | 970 | 81.0 |
| 0.1 | 980 | 79.0 |

IN CASE OF ADDITIVE AMOUNT OF
SILVER TO COPPER IS 6 wt %

| | | |
|---|---|---|
| 0.4 | 1030 | 76.5 |
| 0.3 | 1070 | 74.5 |
| 0.2 | 1100 | 73.5 |
| 0.1 | 1150 | 72.0 |

IN CASE OF ADDITIVE AMOUNT OF
SILVER TO COPPER IS 8 wt %

| | | |
|---|---|---|
| 0.4 | 1100 | 73.0 |
| 0.3 | 1150 | 72.0 |
| 0.2 | 1200 | 71.0 |
| 0.1 | 1230 | 70.0 |

In Table 1, the additive amount of the silver to the copper is changed to 2 wt %, 3 wt %, 6 wt %, and 8 wt %, respectively, and a thickness of the copper-silver alloy plate is changed to 0.1 mm, 0.2 mm, 0.3 mm, and 0.4 mm in all of the cases.

As illustrated in Table 1, it can be grasped that there is a tendency in which the more increased the additive amount of the silver to the copper is, the more the tensile strength is increased and the more the conductivity is decreased. Also, it can be grasped that the thickness of the copper-silver alloy plate also affects the tensile strength and the conductivity, and there is a tendency in which the smaller the thickness is, the more the tensile strength is increased and the more the conductivity is decreased.

Therefore, it can be said that, advisably, the additive amount of the silver to the copper and the thickness of the copper-silver alloy plate are appropriately determined in accordance with a use of the conductive member using the copper-silver alloy.

(2) Etching Process of Copper-Silver Alloy Plate

FIG. 2 is an explanatory view of a method of manufacturing the contact pin 1000 illustrated in FIG. 1. FIG. 2 illustrates: a copper-silver alloy body 100 that is a precursor of the contact pin 1000; and a pipe 10 having translucency and including a wall portion on which a mask pattern 15 (here, schematically illustrated by shading) conforming to a shape of the contact pin 1000 is formed. Note that the copper-silver alloy body 100 illustrated in FIG. 2 is obtained by cutting, into a size of the contact pin 1000, a large copper-silver alloy body 100 manufactured by the above-described technique.

As is known, a photosensitive substance such as silver iodide, silver bromide, or acrylic is applied to a surface of the copper-silver alloy body 100 by spraying, impregnating, or the like before the copper-silver alloy body 100 is inserted into the pipe 10. At this time, a coupling agent may be applied as necessary to the copper-silver alloy body 100 prior to the application of the photosensitive substance so as to enhance adhesion of the photosensitive substance. Additionally, it is preferable to solidify the photosensitive substance by applying pre-bake treatment whereby the copper-silver alloy body 100 applied with the photosensitive substance is heated at a temperature of about 100° C. to 400° C. for a predetermined period.

The pipe 10 includes quartz glass, calcium fluoride, magnesium fluoride, acrylic glass, aluminosilicate glass, soda lime glass, low thermal expansion glass, silicate glass, acrylic resin, and the like. In a case where the mask pattern 15 is formed on the inner wall, it is preferable that an inner diameter of the pipe 10 be substantially the same as the size of the copper-silver alloy body 100 having the surface on which the photosensitive substance is solidified.

The reason is to: prevent positional deviation between the pipe 10 and the copper-silver alloy body 100 during exposure processing described later; and perform accurate pattern transfer. Therefore, it is sufficient that the inner diameter of the pipe 10 has such a size that the copper-silver alloy body 100 can be inserted into the pipe 10 by press-fitting or the like. Note that the shape of the pipe 10 is not needed to be a cylindrical shape, and may have an elliptical or rectangular cross-section.

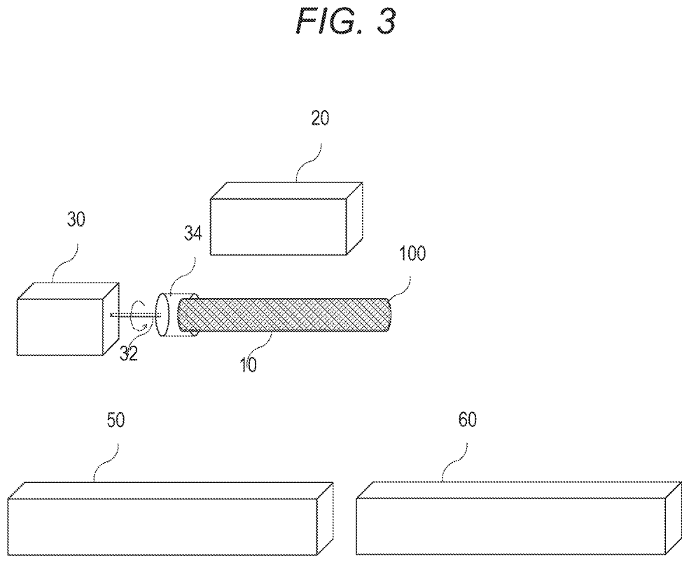

The mask pattern 15 allows ultraviolet light emitted from an exposure device 20 (FIG. 3) to selectively reach the copper-silver alloy body 100, and is the pattern conforming to the shape of the contact pin 1000 that is a final product. A method of forming the mask pattern 15 is not particularly limited, and any known plating method such as electrolytic plating, electroless plating, hot dipping, or vacuum deposition may be employed. A metal film formed by the plating may have a thickness of about 0.5 μm to 5.0 μm, and as a material thereof, nickel, chromium, copper, aluminum, or the like can be used. Note that the mask pattern 15 may include any of a positive type or a negative type.

Additionally, the mask pattern 15 may be formed on either an inner wall or an outer wall of the pipe 100. In a case where the pipe 100 has a small diameter like 2 cm to 3 cm, the mask pattern 15 can be formed on the inner wall of the pipe 100. The light emitted from the exposure device 20 may be changed into parallel light as necessary to increase resolution at the time of exposure.

FIG. 3 is a schematic configuration view of a manufacturing device of the contact pin 1000 according to the embodiment of the present invention. FIG. 3 illustrates: a rotating device 30 that rotates, around an axial center of the pipe 10, the pipe 10 into which the copper-silver alloy body 100 is inserted; the exposure device 20 that emits the ultraviolet light or the like toward a cylindrical surface of the pipe 10; a liquid tank 50 storing developer that develops the copper-silver alloy body 100 exposed by the exposure device 20; and a liquid tank 60 storing etching liquid with which the copper-silver alloy body 100 is impregnated.

Note that respective portions illustrated in FIG. 3 are illustrated for easy understanding of the description, and there may a case where an actual dimensional ratio differs from the illustrated dimensional ratio.

The rotating device 30 includes: a rotating shaft portion 32 connected to a built-in motor (not illustrated); and a pipe receiving portion 34 positioned at a tip of the rotating shaft portion 32. The pipe receiving portion 34 is detachable from the rotating shaft portion 32, and is selectable in accordance with the size of the pipe 10. In the case of the exposure device 20 having the following conditions, the rotating shaft portion 32 is set to be rotated at, for example, a speed of one to two rotations per minute. Therefore, a rotation speed of the rotating shaft portion 32 may be determined in accordance with the exposure conditions. Note that the rotating device 30 may be connected not only to one end of the pipe 10 as illustrated in FIG. 3 but also to both ends thereof.

The exposure device 20 emits the ultraviolet light with a wavelength of about 360 nm to 440 nm (e.g., 390 nm) and an output of about 150 W. Specifically, a xenon lamp, a high-pressure mercury lamp, or the like can be used for the exposure device 20 although the conditions are not limited thereto. Here, a case of providing only one exposure device 20 is exemplified, but an exposure period can be shortened by providing a plurality of exposure devices. Note that, in the case of having the above-described ultraviolet light emitting conditions, a distance between the exposure device 20 and the pipe 10 is to be set to an interval of about 20 cm to 50 cm.

The liquid tank 50 stores the developer to remove an excessive photosensitive material from the copper-silver alloy body 100 that has been applied with the exposure processing by using the exposure device 20. The developer may be selected in accordance with the photosensitive material, but it is possible to use 2.38 wt % aqueous solution of tetra-methyl-ammonium-hydroxide (TMAH) that is an organic alkali.

The liquid tank 60 stores the etching liquid to perform etching after applying the development processing and then performing desired rinse treatment to the copper-silver alloy body 100 that has been exposed by the exposure device 20. As the etching liquid, etching liquid suitable for etching a copper alloy, such as ferric chloride having a specific gravity of about 1.2 to 1.8 or mixture liquid including ammonia persulfate and mercuric chloride, is selected. However, it is also possible to further selectively add a small amount (e.g., about 5%) of etching liquid suitable for etching silver, such as ferric nitrate liquid having substantially the same specific gravity.

Consequently, even when a silver lump or the like is generated at the time of melting, the silver lump can be prevented from remaining on the surface of the copper-silver alloy body 100 after the etching treatment. But in a case where there is a large additive amount of the ferric nitrate liquid or the like, a ratio of the silver on the surface of the copper-silver alloy body 100 after the etching treatment is reduced, and surface strength of the contact pin 1000 is decreased, which is not preferable.

Next, a method of manufacturing the contact pin 1000 will be described. First, prepare the pipe 10 having the inner wall on which the mask pattern 15 corresponding to a pattern to be formed on the copper-silver alloy body 100 has been formed. As described above, the pipe 10 includes quartz glass and the like.

Additionally, apply the photosensitive material to an outer surface of the copper-silver alloy body 100 as well. After that, apply the pre-bake treatment to the copper-silver alloy body 100 at a temperature of about 100° C. to 400° C. After the photosensitive material on the copper-silver alloy body 100 is thus solidified, insert the copper-silver alloy body 100 into the pipe 10.

Subsequently, attach the pipe 10 to the pipe receiving portion 34 of the rotating device 30, and drive the built-in motor of the rotating device 30. With this driving, the pipe 10 is rotated around the axial center thereof. Next, turn on the exposure device 20 to exposure the pipe 10 while rotating the pipe 10 into which the copper-silver alloy body 100 is inserted.

After that, take out the copper-silver alloy body 100 from the pipe 10 and impregnate the copper-silver alloy body 100 for about several tens of seconds (e.g., 20 seconds) in the liquid tank 50 storing the developer. Thus, the excessive photosensitive material is removed from the copper-silver alloy body 100. Subsequently, as is known, apply the rinse treatment to the copper-silver alloy body 100, and then impregnate the copper-silver alloy body 100 in the liquid tank 60 storing the etching liquid. The impregnation period may be determined in accordance with the material, the thickness, and the like of the copper-silver alloy body 100, but generally may be set to 2 to 15 minutes, for example, 10 minutes or less. With the above-described processes, the contact pin 1000 having a desired shape can be manufactured.

Note that, in a case where the surface of the contact pin 1000 is applied with coating treatment to provide a thickness of about 2 μm to 3 μm by using carbon such as graphene, nano silver, or the like by performing electrolytic plating, vacuum deposition, electrostatic spraying, or the like, a conductive property can be further enhanced, and allowable current in the contact pin 1000 can be improved.

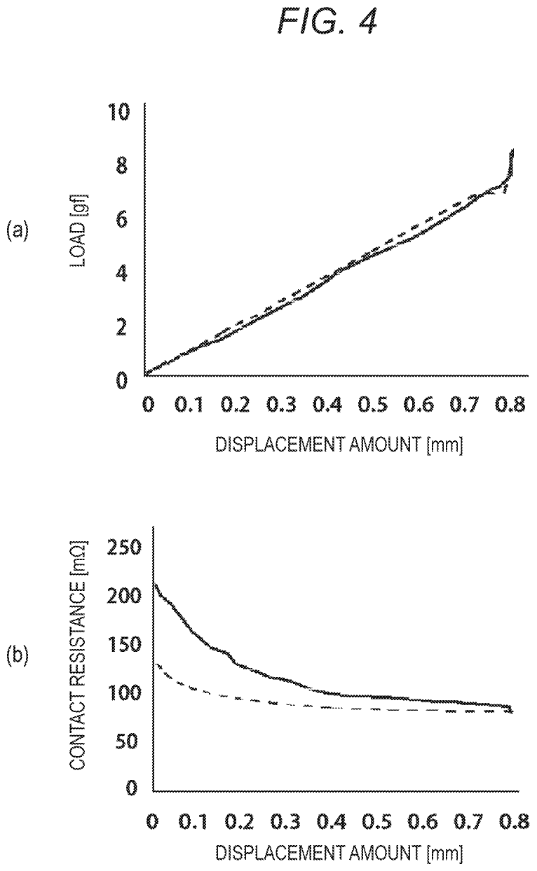

FIG. 4 is a diagram illustrating evaluation results of the contact pin 1000 manufactured by using the copper-silver alloy plate manufactured while setting, to 6 wt %, an additive amount of silver to copper. The contact pin 1000 to be evaluated has the size described with reference to FIG. 1 and has an entire length of about 20 mm and a thickness of about 0.2 mm. Note that an evaluation test illustrated in FIG. 4 provides an average value in a case of displacing the contact pin 1000 by a displacement amount of 0.8 [mm] 10,000 times. Additionally, it is found that there is no deterioration in a function and performance of the contact pin 1000 even after the execution of 10,000 times.

FIG. 4(a) illustrates a relation between a moved amount and a load of the contact pin 1000. Note that, in FIG. 4(a), a horizontal axis represents the displacement amount [mm] of the contact pin 1000, and a vertical axis represents the load [gf] of the contact pin 1000. FIG. 4(b) illustrates a relation between the moved amount and contact resistance of the contact pin 1000. Note that, in FIG. 4(b), a horizontal axis represents the displacement amount [mm] of the contact pin 1000, and a vertical axis represents a contact resistance value [mΩ] related to the conductivity of the contact pin 1000.

Additionally, a solid line illustrated in each of FIGS. 4(a) and 4(b) represents the load and the contact resistance value in a case where the displacement amount of the contact pin 1000 is shifted from 0 [mm] to 0.8 [mm], and a broken line represents the load and the contact resistance value in a case where the displacement amount of the contact pin 1000 is shifted from 0.8 [mm] to 0 [mm].

According to FIG. 4(a), the load is 10 [gf] or less in both of the cases where the displacement amount of the contact pin 1000 is shifted from 0 [mm] to 0.8 [mm] and shifted from 0.8 [mm] to 0 [mm].

According to FIG. 4(b), it is found that: in the case where the displacement amount of the contact pin 1000 is shifted from 0 [mm] to 0.8 [mm], the contact resistance value is 100 [mΩ] or less when the displacement amount becomes about 0.25 [mm] or more; and in the case where the displacement amount is shifted from 0.8 [mm] to 0 [mm], the contact resistance value is 100 [mΩ] or less until the displacement amount reaches about 0.1 [mm].

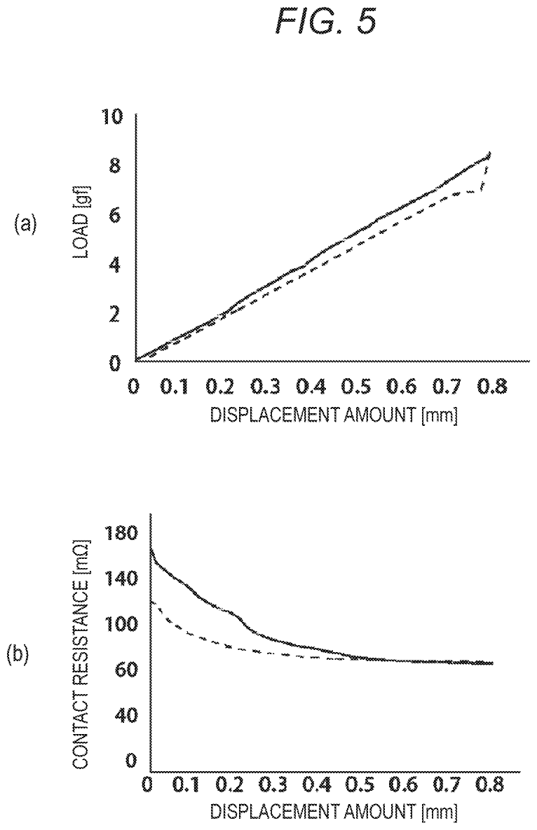

FIG. 5 is a diagram illustrating evaluation results of the contact pin 1000 manufactured by using a copper-silver alloy plate manufactured while setting, to 10 wt %, an additive amount of silver to copper. The contact pin 1000 to be evaluated has the size described with reference to FIG. 1 and has an entire length of about 20 mm and a thickness of about 0.2 mm. Note that an evaluation test illustrated in FIG. 5 is an average value in the case of displacing the contact pin 1000 by a displacement amount of 0.8 [mm] 10,000 times. Additionally, it is found that there is no deterioration in a function and performance of the contact pin 1000 even after the execution of 10,000 times.

FIG. 5(a) illustrates a relation between the moved amount and the load of the contact pin 1000. Note that, in

FIG. 5(a), a horizontal axis represents the displacement amount [mm] of the contact pin 1000, and a vertical axis represents the load [gf] of the contact pin 1000. FIG. 5(b) illustrates a relation between the moved amount and the contact resistance of the contact pin 1000. Note that, in FIG. 5(b), a horizontal axis represents the displacement amount [mm] of the contact pin 1000, and a vertical axis represents the contact resistance value [mΩ] related to the conductivity of the contact pin 1000.

According to FIG. 5(a), the load is 10 [gf] or less in both of the cases where the displacement amount of the contact pin 1000 is shifted from 0 [mm] to 0.8 [mm] and shifted from 0.8 [mm] to 0 [mm].

According to FIG. 5(b), it is found that: in a case where the displacement amount of the contact pin 1000 is shifted from 0 [mm] to 0.8 [mm], the contact resistance value is 100 [mΩ] or less when the displacement amount becomes about 0.35 [mm] or more; and in the case where the displacement amount is shifted from 0.8 [mm] to 0 [mm], the contact resistance value is 100 [mΩ] or less until the displacement amount reaches about 0.1 [mm].

Meanwhile, in recent years, a displacement amount of a contact pin is about 0.1 [mm] to 0.3 [mm] in a semiconductor wafer inspection device, and in this case, it is required that the load is about 4 [gf] or less and the contact resistance value is 200 [mΩ] or less, but as it can be grasped from all of the evaluation results in FIGS. 4 and 5, the contact pin 1000 satisfies the requirements.

Additionally, in recent years, a displacement amount of a contact pin is about 0.5 [mm] in a test socket device for an IC package, and in this case, it is required that the load is about 25 [gf] or less and the contact resistance value is 200 [mΩ] or less, but as it can be grasped from all of the evaluation results in FIGS. 4 and 5, the contact pin 1000 satisfies the requirements

Furthermore, in recent years, a displacement amount of a contact pin is about 1.0 [mm] in an electronic circuit such as a probe pin or a checker pin and a board on which such an electronic circuit is mounted, and in this case, it is required that the load is about 10 [gf] to 20 [gf] or less and the contact resistance value is 200 [mΩ] or less, but as it can be grasped from all of the evaluation results in FIGS. 4 and 5, the contact pin 1000 satisfies the requirements

Moreover, in recent years, a displacement amount of a contact pin is about 0.7 [mm] in a battery inspection device, and in this case, it is required that the load is about 14 [gf] or less and the contact resistance value is 100 [mΩ] or less, but as it can be grasped from all of the evaluation results in FIGS. 4 and 5, the contact pin 1000 satisfies the requirements.

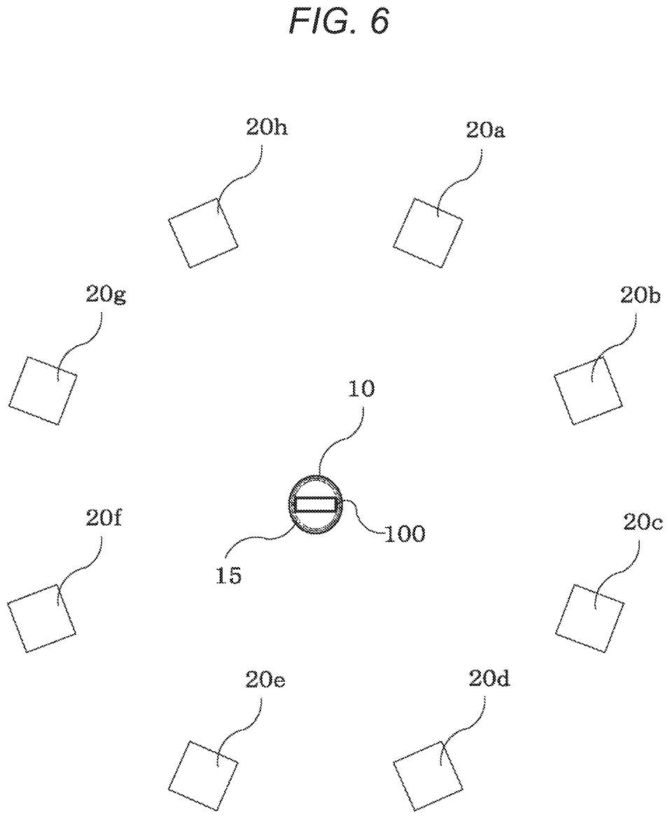

FIG. 6 is an explanatory view of a modified example of the manufacturing device in FIG. 3. FIG. 6 illustrates the pipe 10 and exposure devices 20a to 20h. FIG. 6 is a view from an axial center direction of the pipe 10 in FIG. 3. FIG. 3 illustrates an example in which exposure is performed only by one exposure device 20, but here, a state in which, for example, the cylindrical surface of the pipe 10 is surrounded by the eight exposure devices 20a to 20h is illustrated.

Thus, in the case of exposing the pipe 10 by the plurality of exposure devices 20a to 20h, the cylindrical surface of the pipe 10 can be thoroughly exposed without providing the rotating device 30 to rotate the pipe 10. Due to this, there is an advantage that installation of the rotating device 30 is unnecessary in the exemplary case of FIG. 6.

As described above, in the present embodiment, the manufacturing device of the contact pin 1000 and the method of manufacturing the contact pin 1000 constituting a semiconductor tester have been exemplified while setting the contact pin as the example of the conductive member, but the conductive member can also be used as a conductive material of a member other than the contact pin 1000. Specifically, a connector like an interposer, a probe, a tester including an IC socket, an industrial spring used in a voice coil motor or the like, a suspension wire for an optical image stabilizer used for camera shake correction, and the like are exemplified.

Furthermore, in the present embodiment, the example of manufacturing the copper-silver alloy plate has been described, but not limited to plate material, for example, a round wire member having a diameter in accordance with the use may also be manufactured. As a result, in a case where a product finally obtained by using the conductive material has a cylindrical shape as described above or is the spring or the like exemplified above, cutting work from the copper-silver alloy plate can be omitted, and the manufacturing process can be simplified. In other words, a copper-silver alloy body having a shape conforming to a shape of a final product can also be manufactured with the conductive member of the present embodiment.

1. A contact pin comprising a copper-silver alloy body,
wherein an additive amount of silver to copper is 0.2 wt % to 15 wt %, and in a case where a displacement amount of the contact pin is 0.1 [mm] to 0.3 [mm], a load is 4 [gf] or less.

2. The contact pin according to claim 1, having a planar shape including a spring portion formed in a snake-like S shape.

3. The contact pin according to claim 1, having a three-dimensional shape including a cylindrical shape.

4. The contact pin according to claim 1, having a surface applied with coating treatment with a conductive substance.

5. The device comprising a contact pin according to claim 1.

6. A method of manufacturing a copper-silver alloy body for a contact pin, obtained by applying etching treatment by using at least copper alloy etching liquid, the method comprising:
adding 0.2 wt % to 15 wt % silver to copper;
generating a copper-silver alloy by melting the copper added with the silver; and
applying cold rolling to the melted copper-silver alloy.
